(19) United States
(12) Patent Application Publication
(10) Pub. No.: US 2017/0316811 A1
(43) Pub. Date: Nov. 2, 2017

(54) OPERATION OF VOLTAGE REGULATOR FOR SUBSYSTEM IN CONSTANT CURRENT MODE AND THEN IN CONSTANT VOLTAGE MODE

(71) Applicant: Hewlett Packard Enterprise Development LP, Houston, TX (US)

(72) Inventor: Melvin K. Benedict, Magnolia, TX (US)

(21) Appl. No.: 15/142,800

(22) Filed: Apr. 29, 2016

(51) Int. Cl. G11C 5/14; H02M 3/04

(52) U.S. Cl. CPC G11C 5/147; H02M 3/04

(57) ABSTRACT

At power, a voltage regulator operates in a constant current mode to provide a constant current to a subsystem. The constant current is predetermined as an optimal current to provide to the subsystem to reach normal operation in a temporally efficient manner. When a voltage provided by the voltage regulator reaches a threshold voltage, the voltage regulator operates in a constant voltage mode to provide a constant voltage to the subsystem.

### BACKGROUND

A computing system like a computing device such as a server can include a memory subsystem. The memory subsystem can include a number of memory modules. The memory modules can be dual-inline memory modules (DIMMs), for instance. The memory capacity of the computing system depends on both the number of memory modules and the memory capacity of each memory module.

### BRIEF DESCRIPTION OF THE DRAWINGS

FIG. 1 is a diagram of an example electrical schematic of the capacitive load of a memory subsystem.

FIG. 2 is a timing diagram of example operation of a voltage regulator first in a constant current mode and then in a constant voltage mode.

FIGS. 3 and 4 are flowcharts of example methods for operating a voltage regulator to provide power to a subsystem of a system.

FIGS. 5 and 6 are diagrams of example controllers for a voltage regulator providing power to a subsystem of a system.

FIG. 7 is a diagram of an example system including a subsystem, a voltage regulator providing power to the subsystem, and a controller for the voltage regulator.

### DETAILED DESCRIPTION

As noted in the background, a computing system can include a memory subsystem having a number of memory modules like dual-inline memory modules (DIMMs). The memory subsystem of a computing system can have its own power subsystem apart from the rest of the computing system. For example, the memory subsystem may have its own voltage regulator, which regulates the voltage provided just to the memory subsystem.

A memory system exhibits an unknown and variable capacitive load to the voltage regulator. As the number of memory modules and/or the memory capacity and thus density of each memory module increases, the capacitive load of the memory subsystem exposed to the voltage regulator increases as well. When the memory subsystem is powered on, this capacitive load results in a large inrush current having to be provided by the voltage regulator until the subsystem is fully powered and can operate normally.

If the inrush current is too great, however, then the voltage regulator can fail, or a power-tripping mechanism of the memory subsystem or of the computing system as a whole, such as a circuit breaker or a fuse, can trip. One approach to avoid this problem is to control the rate at which the voltage regulator transitions from zero voltage to operating voltage. This rate, however, is a “best guess” and is memory subsystem-specific, since the number of memory modules and the memory capacity of each memory module dictate the capacitive load of the subsystem and thus the rate at which the regular regulator should transition from zero voltage to operate voltage to prevent a too great inrush current.

If the rate is selected incorrectly, the inrush current may still cause the power-tripping mechanism to trip. As the memory capacities of memory modules increase, this problem is exacerbated. A memory subsystem that can properly power on at a certain memory capacity may still result in tripping at a greater memory capacity, because the increased capacitive load results in an inrush current greater than that which the voltage regulator's transition rate from zero voltage to operating voltage can accommodate.

Disclosed herein are techniques to control a voltage regulator providing power to a subsystem, like a memory subsystem, that avoids these shortcomings. At power on, the voltage regulator operates in a constant current mode. Once the voltage at the subsystem reaches a threshold voltage, the voltage regulator operates in a constant voltage mode. The constant current provided in the constant current mode and the capacitive load of the memory subsystem dictate the length of time the voltage regulator operates in the constant current mode.

Therefore, the problems noted above are avoided. There is no need to guess the maximum capacitive load of a memory subsystem and indeed no need to specify a rate at which a voltage regulator transitions from zero voltage to operating voltage. By operating in a constant current mode at power on, the voltage regulator can effectively accommodate nearly any memory subsystem capacitive load, and thus nearly any amount of memory capacity of the subsystem. The current provided in the constant current mode may be specified based on an estimate of the subsystem's capacitive load for optimal speed in the subsystem reaching normal operation. However, even if the constant current is specified based on a worst-case capacitive load, the worst-case scenario is that reaching normal operation will take slightly longer—and will not trip a power-tripping mechanism or damage the voltage regulator.

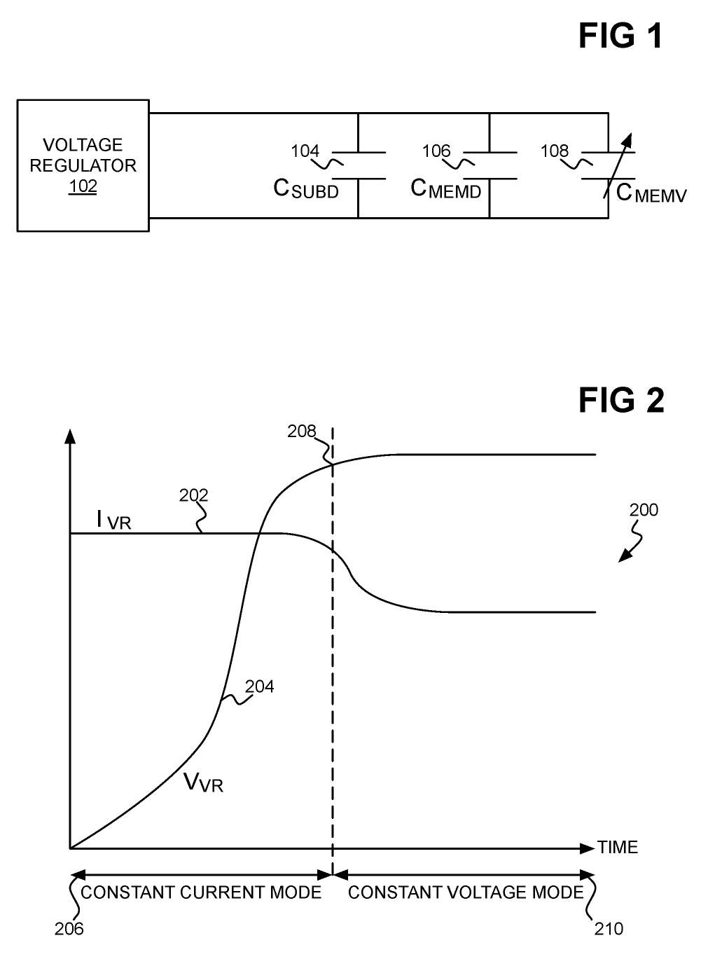

FIG. 1 schematically shows an example capacitive load of a memory subsystem of a computing system from a perspective of a voltage regulator 102. The capacitive load is the sum of three capacitances 104, 106, and 108. The capacitance 104, or C_{SUBD}, is the total decoupling capacitance of the memory subsystem as a whole, including, for instance, the decoupling capacitance of the power distribution platform for the computing system as it affects the voltage regulator 102. The capacitance 106, or C_{MEMD}, is the total decoupling capacitance of the memory modules of the memory subsystem. The capacitance 108, or C_{MEMV}, is the variable capacitance of the memory on the memory modules, which increases as the voltage provided to the memory subsystem by the voltage regulator 102 increases from zero at power on to the voltage at which the subsystem is operational.

The decoupling capacitances 104 and 106 can result from decoupling capacitors used to isolate noise within the various subsystems of the computing system. The decoupling capacitances 104 and 106 can thus be static values. By comparison, the capacitance 108 is the variable capacitance of the memory on the memory modules. During power on, the capacitance 108 is a function of the instantaneous voltage being provided by the voltage regulator 102. This voltage may increase to a peak value and then decrease to nominally constant during normal operation. Because current is equal to

$${C}_{t} \frac{{d}_{v}}{{d}_{t}} ,$$

where Cₜ is the total instantaneous capacitance (i.e., the sum of capacitances 106, 108, and 108) at a given time t and

$$\frac{{d}_{v}}{{d}_{t}}$$

is the derivative of the instantaneous voltage being provided to the subsystem at this time t with respect to time, when the subsystem is first powered on, the current can be relatively large for a brief length of time until the voltage reaches a near constant value during normal operation.

FIG. 2 shows a timing diagram of example operation of the voltage regulator 102. The x-axis denotes time, whereas the y-axis denotes both current being provided by the voltage regulator 102, as indicated by the line 202 labeled I_{VR}, and voltage being provided by the voltage regulator 102, as indicated by the line 204 labeled V_{VR}. At power on, the voltage regulator 102 operates in a constant current mode 206. As such, the current provided by the voltage regulator 102 is constant.

While the voltage regulator 102 provides constant current, the voltage provided by the voltage regulator 102 increases as the capacitances 104, 106, and 108 become charged. Once the voltage reaches a threshold voltage indicated at the point 208, the voltage regulator 102 switches operation from the constant current mode 206 to a constant voltage mode 210. As such, the voltage provided by the voltage regulator 102 is constant. The current provided by the regulator 102 in the constant voltage mode 210 also stays constant while the subsystem to which the voltage regulator 102 is providing power operates normally.

By initially operating the voltage regulator 102 in the constant current mode 206 and then operating the regulator 102 in the constant voltage mode 210 once the threshold voltage has been reached, the exact rate at which the voltage provided by the voltage regulator 102 transitions from zero voltage to operating voltage does not have to be controlled. This is because in the constant current mode 206, the inrush current to the subsystem is limited to the constant current provided in this mode 206. So long as the constant current provided in the constant current mode 206 is selected to be less than that which will result in a power-tripping mechanism like a circuit breaker or fuse from tripping, there is in essence no chance for such tripping to occur.

If the capacitive load placed on the voltage regulator 102 increases by increasing the number of memory modules and/or the capacity of each memory module, for instance, the current cannot correspondingly increase because it is limited to a constant value in the constant current mode 206. The only effect of such an increased capacitive load may be a slightly longer length in time in the voltage provided by the voltage regulator 102 reaching the threshold voltage. Therefore, the rate at which the regulator 102 transitions from zero voltage to operating voltage advantageously does not have to be estimated, nor indeed the capacitive load on the voltage regulator 102, to ensure that tripping does not occur.

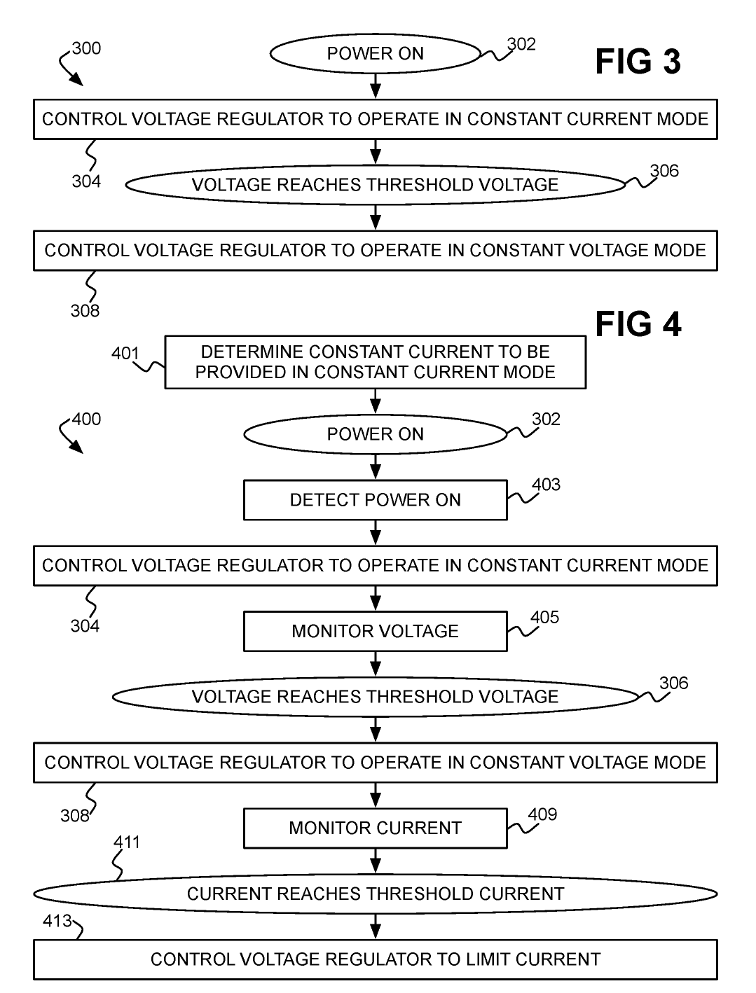

FIG. 3 shows an example method 300 for controlling the voltage regulator 102 to provide power to a subsystem like a memory subsystem of a system such as a computing system. The method 300 may be performed by a controller of or for the voltage regulator 102. At power on of the voltage regulator 102 and thus of the subsystem (302), the controller controls the voltage regulator 102 to operate in the constant current mode 206 (304). Once the voltage that the regulator 102 provides to the subsystem—and thus the voltage at or over the subsystem—reaches a threshold voltage (306), the controller controls the voltage regulator 102 to instead operate in the constant voltage mode 210 (308).

The constant current that the voltage regulator 102 is to provide in the constant current mode 206 to the subsystem can be predetermined, as the optimal current to provide to the subsystem that permits the subsystem to reach normal operation as quickly as possible (that is, in a temporally efficient manner). This constant current may be the maximum that the regulator 102 can provide to the subsystem that does not result in tripping, which is based on the capabilities of the regulator 102. One particular implementation is now described.

For example, as noted above, for a memory subsystem, the capacitive load on the voltage regulator 102 is the sum of the capacitances 104, 106, and 108 of FIG. 1. The decoupling capacitances 104 and 106 are static and may be known a priori. The variable capacitance 108 of the memory modules can be at least estimated by determining the number of memory modules and the memory capacity of each module—that is, by determining the total memory capacity of the memory subsystem.

Further, each memory module may be able to be interrogated if it supports serial presence detect (SPD), which is a methodology by which parameters of a memory module, including its density, can be retrieved. By thus retrieving these parameters of each memory module, the capacitance 108 can be estimated or determined by, for instance, looking up the capacitance of each memory module in a lookup table using the module's parameters and corresponding the total capacitance load on the voltage regulator 102 to a specified constant current, again such as by using a lookup table. More generally, then, the constant current to be provided by the regulator 102 in the constant current mode may be determined by retrieving component parameters from the parameters of the subsystem, and setting the constant current based on these parameters.

FIG. 4 shows another example method 400 for controlling the voltage regulator 102 to provide power to a subsystem like a memory subsystem of a system such as a computing system. The method 400 is more detailed than but consistent with the method 300. At least some parts of the method 400 may also be performed by a controller of or for the voltage regulator 102.

The constant current to be provided in the constant current mode is determined (401), as described above. The voltage regulator 102 and the subsystem are then powered on (302). The controller may at least implicitly detect such power on (403). For example, when the voltage regulator 102 and the subsystem are powered on, the controller for the regulator 102 may also be powered on at the same time, which means that power on is detected by virtue of the controller having been turned on. The controller may also more explicitly detect that the voltage regulator 102 and the subsystem have been powered on by, for instance, detecting that power that the regulator 102 is provided to the subsystem is non-zero.

The controller controls the voltage regulator 102 to operate in the constant current mode (304), and then monitors the voltage that the regulator 102 provides to the subsystem (405). As such, the controller detects when this voltage reaches the threshold voltage (306). The threshold voltage may be set to a percentage of the nominal operating voltage of the subsystem, such as 90%, 95%, and so on. In response to detecting that the voltage that the voltage regulator 102 provides to the subsystem has reached the threshold voltage, the controller controls the regulator 102 to operate in the constant voltage mode (308).

The controller can also monitor the current that the voltage regulator 102 is providing to the subsystem (409), such as at least when the regulator 102 is operating in the constant voltage mode. While when the subsystem is operating normally the amount of current that the regulator 102 provides to the subsystem in the constant voltage mode is also nominally constant, if the subsystem fails it may draw an amount of current greater than that which results in tripping. For example, if an electrical short develops in the subsystem, the subsystem may attempt to draw essentially an infinite amount of current from the voltage regulator 102.

Therefore, if the controller detects that the voltage regulator 102 is providing current to the subsystem greater than a threshold current (411)—that is, if the current drawn by the subsystem reaches a threshold current—then the controller controls the voltage regulator to limit the amount of current provided to the subsystem (413). As such, overcurrent protection for the subsystem is achieved. The threshold current may be set to a value just less than the amount of current that would result in tripping. Providing overcurrent protection ensures that if the subsystem begins to fail, the entire system may not as a whole catastrophically fail, and may prevent damage to the subsystem and/or other parts of the system of which the subsystem is a part.

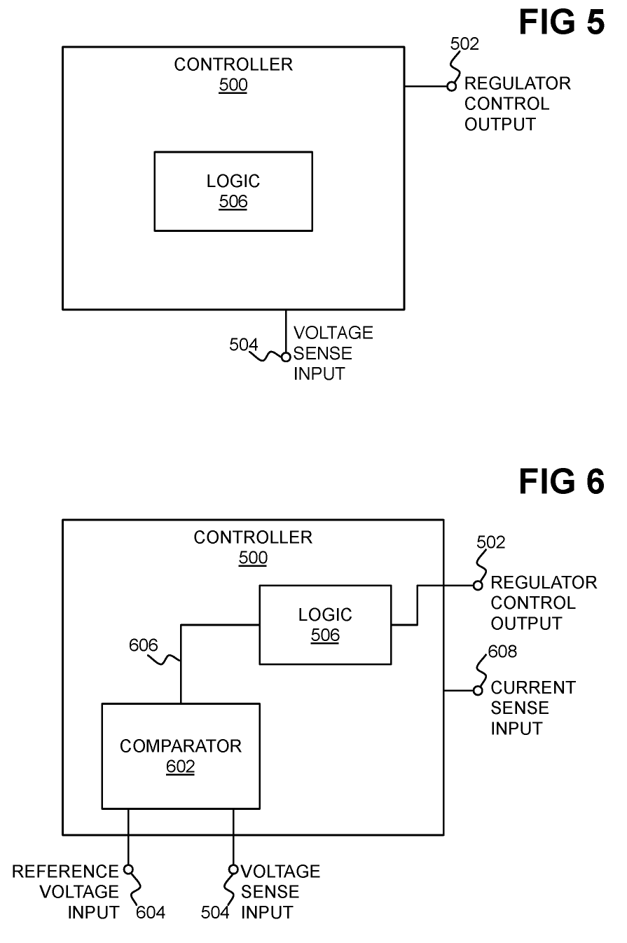

FIG. 5 shows an example controller 500 for the voltage regulator 102. The controller 500 may be implemented completely in hardware, such as an integrated circuit (IC), or may be implemented in a combination of hardware and software, such as including a processor that executes computer-executable code stored on a computer-readable data storage medium. The controller 500 includes a regulator control output 502, a voltage sense input 504, and logic 506.

The regulator control output 502 is coupled to the voltage regulator 102 to control the regulator 102 to operate in the constant current mode 206 or the constant voltage mode 210. The voltage sense input 504 is coupled to the voltage regulator 102 to sense the voltage that the regulator 102 is currently providing to a subsystem of a system. The logic 506 may be implemented completely in hardware, such as an application-specific IC (ASIC), or may be implemented in a combination of hardware and software, as noted above. The logic 506 initially controls the voltage regulator 102 to provide constant current to the subsystem, and when the voltage provided by the regulator 102 reaches a threshold voltage, then controls the regulator 102 to provide a constant voltage to the subsystem.

FIG. 6 shows an example controller 500 for the voltage regulator 102 consistent with but more detailed than in FIG. 5. The controller 500 in FIG. 6 again includes the regulator control output 502, the voltage sense input 504, and the logic 506. The controller 500 of FIG. 6 also can include a comparator 602 that has the voltage sense input 504 as well as a reference voltage input 604 and an output 606, and a current sense input 608.

A reference voltage that is the threshold voltage which dictates when the logic 506 switches the voltage regulator 102 from the constant current mode 206 to the constant voltage mode 210 is provided at the reference voltage input 604. The comparator 602 compares the voltage provided by the voltage regulator 102 at the voltage sense input 504 to the threshold voltage at the reference voltage input 604. The logic 506 operates the voltage regulator 102 in either the constant current mode 206 or the constant voltage mode 210 depending on the result of this comparison, as provided at the output 606 of the comparator 602 to which the logic 506 is communicatively coupled.

For example, in one implementation, if the voltage at the voltage sense input 504 is greater than the voltage at the reference voltage input 604, then the output 606 is high, such as logic one, and otherwise is low, or logic zero. Therefore, when the output 606 is low in this implementation, the logic 506 controls the voltage regulator 102 via the regulator control output 502 to operate in the constant current mode 206. When the output 606 is high, the logic 506 controls the regulator 102 to operate in the constant voltage mode 210.

In another implementation, the output 606 may include two specific output lines, one corresponding to the constant current mode 206 and another corresponding to the constant voltage mode 210. The comparator 606 may assert the former line high and the latter line low when the voltage at the voltage sense input 504 is less than the voltage at the reference voltage input 604. The comparator 606 may assert the line corresponding to the constant current mode 206 low and the line corresponding to the constant voltage mode 210 high when the voltage at the voltage sense input 504 is greater than the voltage at the reference voltage input 604. The logic 506 then controls the voltage regulator 102 to operate in the constant current mode 206 or the constant voltage mode 210 depending on which mode's corresponding line is high.

The current sense input 608 is at least indirectly coupled to the voltage regulator 102 to sense the current that the regulator 102 is currently providing to the subsystem. The logic 506 is to control the voltage regulator 102, at least in the constant voltage mode 210, to limit the current provided by the regulator 102 to the subsystem to a predetermined maximum current if the current exceeds a threshold current. As such, the controller 500 provides overcurrent protection for the subsystem, as has been described above.

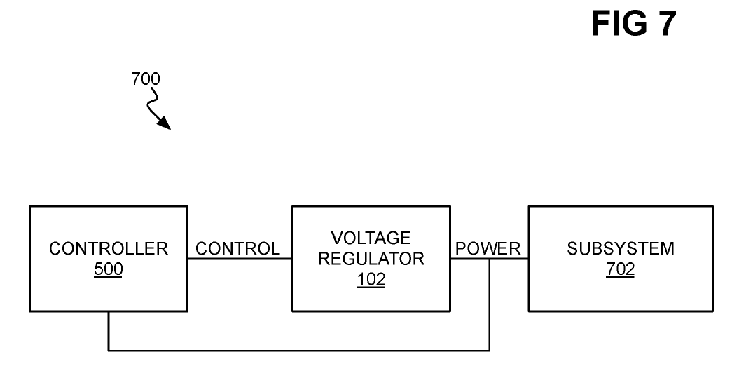

FIG. 7 shows an example system 700. The system 700 can be a computing system, such as a computing device like a computer. The system 700 includes a subsystem 702, the voltage regulator 102 that provides power to the subsystem 702, and the controller 500 for the regulator 102. The subsystem 702 may be a memory subsystem, for instance, including multiple memory modules, such as DIMMs, of unknown capacitive load to the voltage regulator 102. Such a memory subsystem is an example of an entity, for instance, that presents an unknown and variable capacitive load to the voltage regulator 102 at power on of the system 700. The memory subsystem may include, for example, an ASIC having embedded memory, dynamic logic arrays, and other components. The controller 500 operates the voltage regulator 102 in the constant current mode 206 at power on, and then operates the regulator 102 in the constant voltage mode 210 after the voltage at the subsystem 702 (provided by the regulator 102) reaches a threshold voltage.

The techniques that have been described provide a novel manner by which to control a voltage regulator 102 that provides power to a subsystem 702. Instead of having to control the rate at which the power the regulator 102 provides to the subsystem 702 transitions from zero voltage to normal operating voltage, the techniques operate the voltage regulator 102 in a constant current mode 206 at power on. No estimate or guess of such a transition rate, and thus no estimate or guess of the capacitive load of the subsystem 702 on the voltage regulator 102, is required. As such, the likelihood that tripping occurs is minimized if not eliminated, since there is no potential that of an incorrect estimate or guess. Once the voltage that the regulator 102 provides reaches a threshold voltage, the voltage regulator 102 operates in a constant voltage mode 210.

1. A method comprising:
setting a threshold voltage at which control of a voltage regulator is to switch after power on from operation in a constant current mode to operation in a constant voltage mode;
at power on, controlling the voltage regulator providing power to a subsystem to operate in the constant current mode in which the voltage regulator provides a constant current to the subsystem, the constant current predetermined as an optimal current to provide to the subsystem to reach normal operation in a temporally efficient manner; and
in response to a voltage provided by the voltage regulator reaching the threshold voltage, controlling the voltage regulator to operate in the constant voltage mode in which the voltage provides a constant voltage to the subsystem.

2. The method of claim 1, wherein the subsystem is a memory subsystem comprising a plurality of memory modules of unknown capacitive load.

3. The method of claim 1, further comprising:
detecting that the subsystem has been powered on; and
monitoring the voltage provided by the voltage regulator in the constant current mode to detect when the voltage reaches the threshold voltage.

4. The method of claim 1, further comprising:
monitoring a current provided by the voltage regulator in the constant voltage mode; and
in response to the current provided by the voltage regulator reaching a threshold current, controlling the voltage regulator to limit the current provided to the subsystem to achieve overcurrent protection for the subsystem.

5. The method of claim 1, further comprising:
determining the constant current to be provided by the voltage regulator in the constant current mode by retrieving component parameters from a plurality of components of the subsystem and setting the constant current based on the component parameters.

6. A controller comprising:
a regulator control output to control a voltage regulator that is to provide power to a subsystem;
a voltage sense input to sense a voltage that the voltage regulator provides to the subsystem; and
logic implemented at least in hardware to:
initially control the voltage regulator to provide a constant current to the subsystem, the constant current predetermined as an optimal current to provide to the subsystem to reach normal operation in a temporally efficient manner; and
when the voltage that the voltage regulator provides to the subsystem reaches a preset threshold voltage, control the voltage regulator to provide a constant voltage to the subsystem.

7. The controller of claim 6, wherein the subsystem is a memory subsystem comprising a plurality of memory modules of unknown capacitive load.

8. The controller of claim 6, further comprising:
a comparator having the voltage sense input and a reference voltage input, a reference voltage provided at the reference voltage input as the threshold voltage,
wherein the comparator has an output having a value based on whether the reference voltage is greater than or less than the voltage provided by the voltage regulator to the subsystem,
and wherein the logic is to use the output of the comparator to determine when to switch the voltage regulator from providing the constant current to providing the constant voltage to the subsystem.

9. The controller of claim 6, further comprising:
a current sense input to sense a current that the voltage regulator provides to the subsystem,
wherein the logic is to control the voltage regulator to limit the current to a predetermined maximum current to provide overcurrent protection for the subsystem.

10. The controller of claim 6, wherein the constant current provided by the voltage regulator is based on component parameters of a plurality of components of the subsystem.

11. A system comprising:
a subsystem;
a voltage regulator to provide power to the subsystem; and
a controller to operate the voltage regulator in a constant current mode at power on, and to operate the voltage regulator in a constant voltage mode after a voltage at the subsystem reaches a preset threshold voltage,
wherein a constant current in the constant current mode is predetermined as an optimal current to provide to the subsystem to reach normal operation in a temporally efficient manner.

12. The system of claim 11, wherein the subsystem is a memory subsystem comprising a plurality of memory modules of unknown capacitive load.

13. The system of claim 11, wherein the controller comprises:
a comparator to compare the voltage at the subsystem to the threshold voltage; and
logic implemented at least in hardware to control the voltage regulator based on a comparison result of the comparator.

14. The system of claim 11, wherein the controller is further to operate the voltage regulator to limit a current at the subsystem to a predetermined maximum current to provide overcurrent protection for the subsystem.

15. The system of claim 11, wherein in the constant current mode the voltage regulator provides a constant current based on component parameters of a plurality of components of the subsystem.
